(19) United States
(12) Patent Application Publication
(10) Pub. No.: US 2025/0275307 A1
(43) Pub. Date: Aug. 28, 2025

(54) LIGHT-EMITTING DIODE CHIP STRUCTURES WITH ELECTRODE EXTENSIONS AND GRADIENT VIAS

(71) Applicant: CreeLED, Inc., Durham, NC (US)

(72) Inventors: David Suich, Durham, NC (US); Michael Check, Holly Springs, NC (US); Joseph G. Sokol, Durham, NC (US); Colin Blakely, Raleigh, NC (US)

(21) Appl. No.: 18/589,641

(22) Filed: Feb. 28, 2024

(51) Int. Cl. H01L 33/38

(52) U.S. Cl. CPC H10H 20/8316

(57) ABSTRACT

Solid-state lighting devices including light-emitting diode (LED) chips and more particularly LED chip structures with electrode extensions and gradient via arrangements are disclosed. Electrode extensions and vias are formed on opposing sides of an active LED structure as part of anode and cathode connections. Gradient via arrangements include variable diameter and/or variable via pitch relative to electrode extensions and electrode pads. Additional structures include variable width electrode extensions relative to vias and/or electrode pads. Layouts of gradient vias and corresponding electrode extensions are disclosed for increasing uniformity in recombination efficiency across LED chip areas and for providing improvements to current injection, current droop, and overall emission efficiency.

### FIELD OF THE DISCLOSURE

The present disclosure relates to solid-state lighting devices including light-emitting diode (LED) chips and more particularly to LED chip structures with electrode extensions and gradient vias.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from gallium nitride, gallium phosphide, aluminum nitride, and/or gallium arsenide-based materials and/or from organic semiconductor materials, among others. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by how well current is able to spread within an LED. To increase current spreading for LEDs, and in particular for larger area LEDs, it has been found useful to add layers of high electrical conductivity over one or more epitaxial layers of an LED. Electrodes for the LEDs can have larger surface areas and may include various electrode extensions or fingers that are configured to route and distribute current across an LED.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diode (LED) chips and more particularly to LED chip structures with electrode extensions and gradient via arrangements. Electrode extensions and vias are formed on opposing sides of an active LED structure as part of anode and cathode connections. Gradient via arrangements include variable diameter and/or variable via pitch relative to electrode extensions and electrode pads. Additional structures include variable width electrode extensions relative to vias and/or electrode pads. Layouts of gradient vias and corresponding electrode extensions are disclosed for increasing uniformity in recombination efficiency across LED chip areas and for providing improvements to current injection, current droop, and overall emission efficiency.

In one aspect, an LED chip comprises: an active LED structure comprising a first layer of a first conductivity type, a second layer of a second conductivity type that is opposite the first conductivity type, and an active layer between the first layer and the second layer; a first electrode pad on a first side of the active LED structure, a first electrode extension and a second electrode extension on the first side of the active LED structure, the first electrode extension and the second electrode extension electrically connected to the first electrode pad; and a plurality of vias on a second side of the active LED structure opposite the first side, the plurality of vias positioned between portions of the active LED structure that are vertically aligned with the first electrode extension and the second electrode extension, and diameters of individual vias of the plurality of vias vary with distance from the first electrode pad. In certain embodiments, the plurality of vias is arranged in a column across the second side of the active LED structure. In certain embodiments, the diameters of individual vias of the plurality of vias progressively decrease with increasing distance from the first electrode pad. In certain embodiments, the diameters of individual vias of the plurality of vias progressively increase with increasing distance from the first electrode pad. The LED chip may further comprise a second electrode pad on the first side of the active LED structure, wherein the first electrode pad is arranged proximate a first edge of the active LED structure, the second electrode pad is arranged proximate a second edge of the active LED structure, and the second edge is opposite the first edge. In certain embodiments, the diameters of individual vias of the plurality of vias progressively decrease with increasing distance from the first electrode pad and the second electrode pad toward a center of the active LED structure. In certain embodiments, the diameters of individual vias of the plurality of vias progressively increase with increasing distance from the first electrode pad and the second electrode pad toward a center of the active LED structure.

The LED chip may further comprise: a second electrode pad, a third electrode pad, and a fourth electrode pad on the first side of the active LED structure; wherein the first electrode pad and the second electrode pad are arranged proximate a first edge of the active LED structure, the third electrode pad and the fourth electrode pad are arranged proximate a second edge of the active LED structure, and the second edge is opposite the first edge. In certain embodiments, the first electrode pad is an electrode bar arranged proximate a first edge of the active LED structure.

In certain embodiments: the active LED structure comprises a first edge and a second edge that are opposite one another, and a third edge and a fourth edge that are opposite one another; the plurality of vias is arranged in a first column of vias and a second column of vias that both extend between the first edge and the second edge of the active LED structure; and positions of vias in the first column of vias are offset relative to positions of vias in the second column in a direction from the third edge to the fourth edge.

In certain embodiments: the plurality of vias is arranged in a first column of vias and a second column of vias; and a total number of vias in the first column of vias is different than a total number of vias in the second column of vias.

In another aspect, an LED chip comprises: an active LED structure comprising a first layer of a first conductivity type, a second layer of a second conductivity type that is opposite the first conductivity type, and an active layer between the first layer and the second layer; a first electrode pad on a first side of the active LED structure, a first electrode extension and a second electrode extension on the first side of the active LED structure, the first electrode extension and the second electrode extension electrically connected to the first electrode pad; and a plurality of vias on a second side of the active LED structure opposite the first side, the plurality of vias positioned between portions of the active LED structure that are vertically aligned with the first electrode extension and the second electrode extension, and a pitch between neighboring vias of the plurality of vias varies with distance from the first electrode pad. In certain embodiments, the plurality of vias is arranged in a column across the second side of the active LED structure, and the pitch increases with increasing distance from the first electrode pad. In certain embodiments, diameters of individual vias of the plurality of vias increase along the column with increasing distance from the first electrode pad. The LED chip may further comprise: a second electrode pad on the first side of the active LED structure, wherein the first electrode pad is arranged proximate a first edge of the active LED structure, the second electrode pad is arranged proximate a second edge of the active LED structure, and the second edge is opposite the first edge; wherein the pitch between neighboring vias of the plurality of vias is highest proximate a center of the first side of the active LED structure. In certain embodiments: the plurality of vias is arranged in a plurality of columns between the first electrode extension and the second electrode extension proximate the first electrode pad; and the plurality of vias is arranged in a single column between the first electrode extension and the second electrode extension in a position that is spaced farther away from the first electrode pad than the plurality of columns. In certain embodiments, diameters of individual vias of the plurality of vias increase with increasing distance from the first electrode pad. In certain embodiments, the first electrode pad is an electrode bar arranged proximate a first edge of the active LED structure. In certain embodiments: the active LED structure comprises a first edge and a second edge that are opposite one another, and a third edge and a fourth edge that are opposite one another; the plurality of vias is arranged in a first column of vias and a second column of vias that both extend between the first edge and the second edge of the active LED structure; and positions of vias in the first column of vias are offset relative to positions of vias in the second column in a direction from the third edge to the fourth edge. In certain embodiments: the plurality of vias is arranged in a first column of vias and a second column of vias; and a total number of vias in the first column of vias is different than a total number of vias in the second column of vias.

In another aspect, an LED chip comprises: an active LED structure comprising a first layer of a first conductivity type, a second layer of a second conductivity type that is opposite the first conductivity type, and an active layer between the first layer and the second layer; an electrode pad on a first side of the active LED structure, a plurality of vias on a second side of the active LED structure opposite the first side, wherein diameters of individual vias of the plurality of vias vary with distance from the electrode pad; and a first electrode extension on the first side of the active LED structure, the first electrode extension electrically connected to the electrode pad, wherein a width of the first electrode extension varies with distance from the electrode pad. In certain embodiments, the width of the first electrode extension progressively decreases with increasing distance from the electrode pad. The LED chip may further comprise a second electrode extension on the first side of the active LED structure, the second electrode extension electrically connected to the electrode pad, wherein a width of the second electrode extension progressively decreases with increasing distance from the electrode pad. In certain embodiments, the plurality of vias is arranged in a column across the second side of the active LED structure between portions of the active LED structure that are vertically aligned with the first electrode extension and the second electrode extension. In certain embodiments, a pitch between neighboring vias of the plurality of vias increases with increasing distance from the electrode pad. In certain embodiments, diameters of individual vias of the plurality of vias increase along the column with increasing distance from the electrode pad. In certain embodiments, the electrode pad is an electrode bar arranged proximate a first edge of the active LED structure. In certain embodiments: the active LED structure comprises a first edge and a second edge that are opposite one another, and a third edge and a fourth edge that are opposite one another; the plurality of vias is arranged in a first column of vias and a second column of vias that both extend between the first edge and the second edge of the active LED structure; and positions of vias in the first column of vias are offset relative to positions of vias in the second column in a direction from the third edge to the fourth edge. In certain embodiments: the plurality of vias is arranged in a first column of vias and a second column of vias; and a total number of vias in the first column of vias is different than a total number of vias in the second column of vias.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-section of a portion of a light-emitting diode (LED) chip illustrating an electrode extension and a via arranged on opposing sides of an active LED structure according to principles of the present disclosure.

FIG. 2 is a top view of an LED chip similar to FIG. 1 with a layout of electrode extensions and vias with variable diameters according to principles of the present disclosure.

FIG. 3 is a top view of an LED chip that is similar to the LED chip of FIG. 2 except diameters of the vias increase with increasing distance from the electrode pads.

FIG. 4 is a top view of an LED chip that is similar to the LED chip of FIG. 2 except diameters of the vias decrease and then increase along each column of vias.

FIG. 5 is a top view of an LED chip that is similar to the LED chip of FIG. 4 except diameters of the vias increase and then decrease along each column of vias.

FIG. 6 is a top view of an LED chip that is similar to the LED chip of FIG. 5 and further includes multiple electrode pads proximate each opposing edge of the LED chip.

FIG. 7 is a top view of an LED chip that is similar to the LED chip of FIG. 3 for embodiments where a pitch of the vias varies with distance from the electrode pad.

FIG. 8 is a top view of an LED chip that is similar to the LED chip of FIG. 7 except electrode pads are positioned proximate opposing edges of the LED chip.

FIG. 9 is a top view of an LED chip that is similar to the LED chip of FIG. 7 for embodiments where vias are formed in multiple columns between portions of adjacent electrode extensions.

FIG. 10 is a top view of an LED chip that is similar to the LED chip of FIG. 7 for embodiments where a width of one or more of the electrode extensions varies with distance from one or more of the electrode pads.

FIG. 11 is a top view of an LED chip that is similar to the LED chip of

FIG. 3 for embodiments where the electrode pad is an electrode bar proximate an edge of the LED chip.

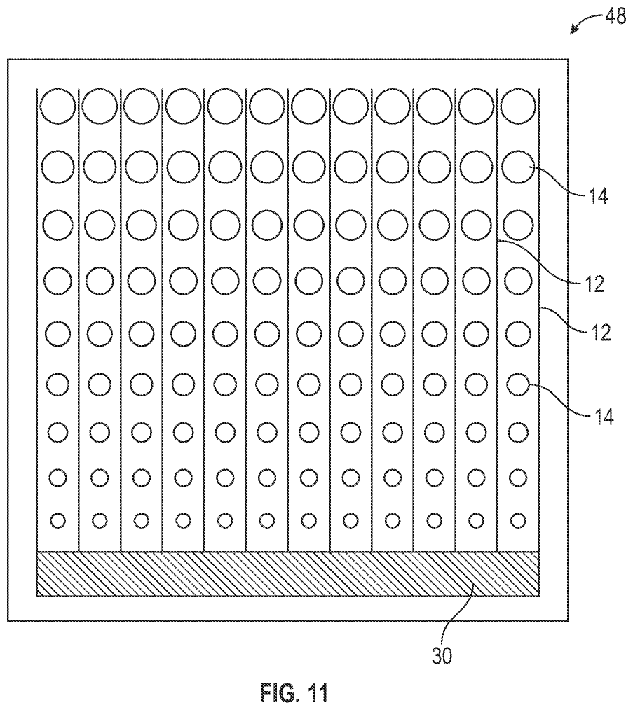

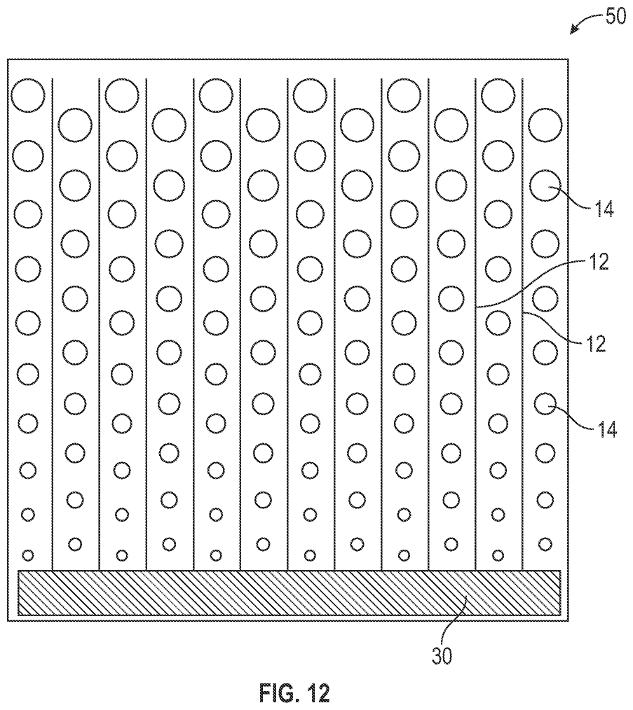

FIG. 12 is a top view of an LED chip that is similar to the LED chip of FIG. 11 for embodiments where positions of vias in each column are offset with positions of vias in adjacent columns.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diode (LED) chips and more particularly to LED chip structures with electrode extensions and gradient via arrangements. Electrode extensions and vias are formed on opposing sides of an active LED structure as part of anode and cathode connections. Gradient via arrangements include variable diameter and/or variable via pitch relative to electrode extensions and electrode pads. Additional structures include variable width electrode extensions relative to vias and/or electrode pads. Layouts of gradient vias and corresponding electrode extensions are disclosed for increasing uniformity in recombination efficiency across LED chip areas and for providing improvements to current injection, current droop, and overall emission efficiency.

An LED chip typically comprises an active LED structure or region that can have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit generally red or yellow light with a peak wavelength range of 600 nm to 700 nm. Certain embodiments as disclosed herein may be well suited for various sub-ranges within 600 nm to 700 nm, such as a peak wavelength range from 650 nm to 670 nm and/or a peak wavelength range from 610 nm to 630 nm, depending on the application. In certain embodiments, aspects of the present disclosure are applicable to an active LED structure that emits light with a peak wavelength in any area of the visible spectrum, for example peak wavelengths primarily in a range from 400 nm to 700 nm.

In still further embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. In certain embodiments, a “light-transmissive” material may be configured to transmit at least 50% of emitted radiation of a desired wavelength.

The present disclosure can be useful for LED chips having a variety of geometries, including vertical geometries. A vertical geometry LED chip typically includes anode and cathode connections on opposing sides or faces of the LED chip. In certain embodiments, a vertical geometry LED chip may also include a growth substrate that is arranged between the anode and cathode connections. In other embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface.

The present disclosure may be useful for LED chips with current spreading structures that distribute current across active LED structure areas. Current spreading structures may include various electrically conductive layers, contacts, electrode extensions or fingers, and/or vias that effectively route current across an LED chip for reduced current crowding. In vertical LED chip structures, n-type and p-type contacts are typically made from opposing sides of the active LED structure. For larger area LED chips, contacts and corresponding electrode extensions may be arranged along a top of the active LED structure to contact one side of the active LED structure while bottom contacts and corresponding vias may be arranged to contact the opposing side of the active LED structure. As used herein, an electrode extension may refer to an elongated electrically conductive material that is continuous with and extends from an electrode pad or contact pad of an LED chip. The electrode pad may receive an external electrical connection, such as a wire bond, and the electrode extension extends away from the electrode pad for current spreading. As used herein, the terms electrode extension, contact extension, electrode finger, and contact finger may be used interchangeably.

As indicated above, principles of the present disclosure are applicable to active LED structures that emit peak wavelengths across a variety of visible and nonvisible ranges. In certain embodiments, aspects of the present disclosure are particularly useful for active LED structures configured to emit generally red or yellow light with a peak wavelength range of 600 nm to 700 nm. Certain embodiments as disclosed herein may be well suited for various sub-ranges within 600 nm to 700 nm, such as a peak wavelength range from 650 nm to 670 nm and/or a peak wavelength range from 610 nm to 630 nm, depending on the application. Such active LED structures may comprise GaP and/or GaAs based materials, such as aluminum indium gallium phosphide (AlInGaP) materials for any of the n-type, p-type, and active layers.

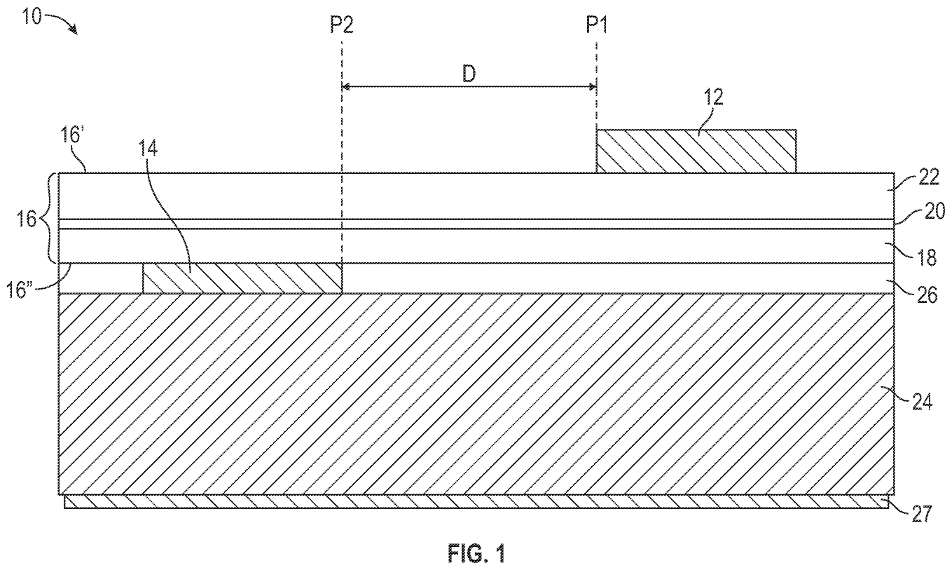

FIG. 1 is a cross-section of a portion of an LED chip 10 illustrating an electrode extension 12 and a via 14 arranged on opposing sides of an active LED structure 16 according to principles of the present disclosure. In FIG. 1, the active LED structure 16 is generally shown with a p-type layer 18, an n-type layer 22, and an active layer 20 therebetween. It is understood the active LED structure 16 may include additional layers and that each of the p-type layer 18, the n-type layer 22, and the active layer 20 may include multiple sublayers. The active LED structure 16 may be formed on a substrate 24. In certain embodiments, the substrate 24 embodies a carrier substrate on which the active LED structure 16 is supported. In such embodiments, the active LED structure 16 may first be grown on a growth substrate, followed by bonding the substrate 24 (e.g., carrier substrate) to a side of the active LED structure that is opposite the growth substrate, and then followed by removal of the growth substrate. In certain embodiments, the p-type layer 18 is between the active layer 20 and the carrier substrate 24 as illustrated in FIG. 1. In other embodiments, it is understood the doping or conductivity order may be reversed so that the n-type layer 22 is between the active layer 20 and the carrier substrate 24. The following discussion of FIG. 1 is in the context of the p-type layer 18 being closer to the carrier substrate 24 than the n-type layer 22. However, it is understood the principles are equally applicable to embodiments where the conductivity types are reversed. The substrate 24 may comprise many different materials, with silicon or other conductive materials being well suited for vertical chip structures.

In FIG. 1, the electrode extension 12 is on a first side 16′ (or top side) of the active LED structure 16 opposite the carrier substrate 24. As will be illustrated in later figures, the electrode extension 12 may extend from a top electrode pad that is also on the first side 16′. The electrode extension 12 provides a portion of an n-contact connection to the n-type layer 22. The LED chip 10 may include one or more electrically insulating layers 26 between the active LED structure 16 and the carrier substrate 24. In one example, the insulating layer 26 may form a portion of a mirror or reflective layer that is positioned to redirect downward propagating light back through the active LED structure 16 and out a top side of the LED chip 10. In this regard, the via 14 is arranged on a second side 16″ (or bottom side) of the active LED structure 16 that is opposite the first side 16′ to provide an electrically conductive path through the insulating layer 26 between the carrier substrate 24 and the active LED structure 16. A bottom electrode pad 27 may be formed on a bottom of the carrier substrate 24. By way of example, the via 14 provides a portion of a p-contact connection between the bottom electrode pad 27 and the p-type layer 18.

As illustrated in FIG. 1, a distance D may be defined as a lateral distance or spacing between the electrode extension 12 and the via 14, as measured in a horizontal plane between closest peripheral edges of the electrode extension 12 and the via 14. Since the electrode extension 12 and the via 14 are on opposing sides of the active LED structure 16, the distance D is measured between a first plane P1 vertically aligned with an edge of the electrode extension 12 and a second plane P2 vertically aligned with an edge of the via 14 that is closest to the electrode extension 12. When electrically activated, the active LED structure 16 generates light by the recombination of electrons and holes proximate the active layer 20. Increased recombination efficiency is realized in portions of the active LED structure 16 that are between the electrode extension 12 and the via 14. As illustrated, the via 14 may be laterally spaced from the electrode extension 12 by the distance D in order to reduce amounts of light lost to absorption by the electrode extension 12. For example, the electrode extension 12 may comprise conductive metals, such as gold (Au) or alloys thereof, that may reflect and/or absorb light generated in the active LED structure 16. By positioning the via 14 with a lateral spacing that is offset by the distance D from a position directly beneath the electrode extension 12, increased amounts of light may escape without interacting with the electrode extension 12. However, the electric potential of electrostatic fields decreases with increased distance D, so if the distance D is too great, the spacing between the via 14 and the electrode extension 12 may include areas with significantly reduced field strength, thereby reducing recombination efficiency.

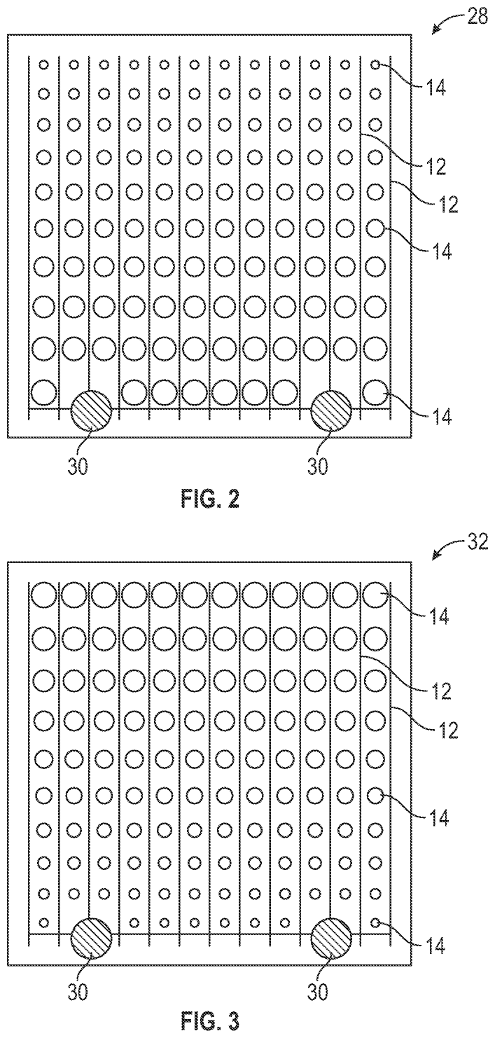

FIG. 2 is a top view of an LED chip 28 similar to the LED chip 10 with a layout of electrode extensions 12 and vias 14 with variable diameters according to principles of the present disclosure. Since the view is from a top of the LED chip 28, the electrode extensions 12 are visible at the top surface of the LED chip 28. The vias 14, while being below the top surface of the LED chip 28, may still be visible therethrough as illustrated in FIG. 2. The electrode extensions 12 are interconnected in a continuous manner with one or more top electrode pads 30 on the top surface. In this manner, the electrode pads 30 may receive external electrical connections, such as wire bonds, and the electrode extensions 12 spread current along the area of the LED chip 28. In FIG. 2, the electrode pads 30 are arranged proximate a same edge of the LED chip 28 and the electrode extensions 12 extend in a linear manner toward the opposing edge of the LED chip 28. In certain embodiments, the electrode extensions 12 and the vias 14 are aligned in alternating linear columns from the top perspective. Such an arrangement provides variable distances between various points on each electrode extension 12 and the closest via or vias 14. Accordingly, certain areas between electrode extensions 12 and closest vias 14 may be positioned in areas of reduced field strength that exhibit reduced recombination efficiency. As illustrated, diameters of the vias 14 vary with distance from the electrode pad 30 to improve recombination efficiency. For example, diameters of the vias 14 may progressively decrease from larger to smaller within each column and with increasing distance from one or more of the electrode pads 30. In this manner, vias 14 with larger diameters are positioned closer to the electrode pads 30 where current injection and/or electric potential may be highest.

FIG. 3 is a top view of an LED chip 32 that is similar to the LED chip 28 of FIG. 2 except diameters of the vias 14 increase with increasing distance from the electrode pads 30. As illustrated, vias 14 with smaller diameters are positioned closer to the electrode pads 30 and vias 14 with the largest diameters are positioned at or near distal ends of the electrode extensions 12 proximate an opposite edge of the LED chip 32. In such embodiments, vias 14 with larger diameters are positioned farthest from the electrode pads 30 where current injection may be lowest. The selection of having the vias 14 grade from larger to smaller diameters (e.g., FIG. 2) with distance from the electrode pads 30 or from smaller to larger diameters (e.g., FIG. 3) with distance from the electrode pads 30 may be determined by various factors. Such factors may include electrostatic field differences related to various LED chip structures, material systems, and/or current spreading capabilities of electrode extensions 12. Other factors and/or benefits include helping drive more uniform distribution of carriers (i.e., holes and electrons) that results in improved recombination efficiency for light generation and reducing localized heating from localized carrier concentrations.

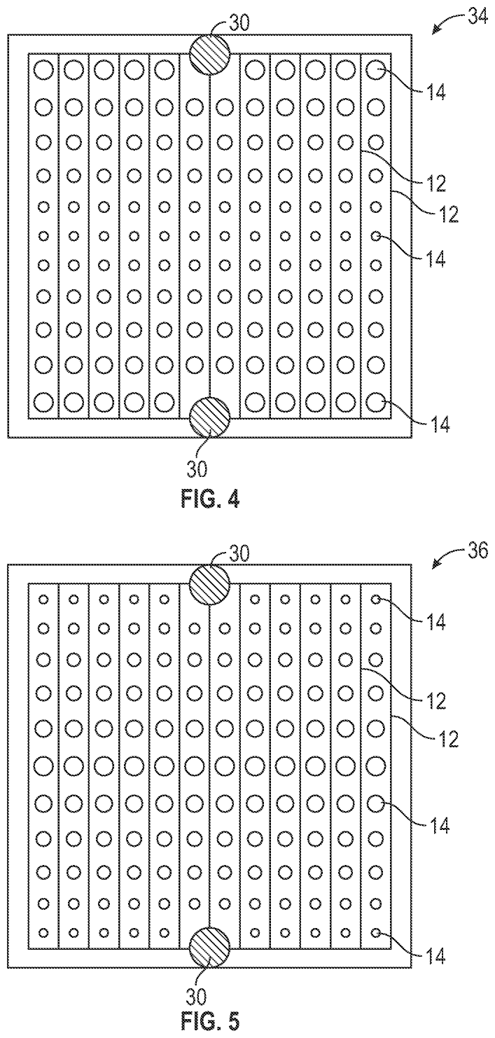

FIG. 4 is a top view of an LED chip 34 that is similar to the LED chip 28 of FIG. 2 except diameters of the vias 14 decrease and then increase along each column of vias 14. In certain embodiments, the electrode pads 30 may be arranged proximate opposing sides of the LED chip 34. Accordingly, diameters of the vias 14 in each column may decrease with increasing distance from each opposing electrode pad 30 toward a center of the LED chip 34. In this manner, vias 14 with smaller diameters are arranged along center portions of the LED chip 34 that are between the opposing electrode pads 30. In certain embodiments, one or more, or even all of the electrode extensions 12 may form a continuous structure with both of the electrode pads 30.

FIG. 5 is a top view of an LED chip 36 that is similar to the LED chip 34 of FIG. 4 except diameters of the vias 14 increase and then decrease along each column of vias 14. In certain embodiments, the electrode pads 30 may be arranged proximate opposing sides of the LED chip 36. Accordingly, diameters of the vias 14 in each column may increase with increasing distance from each opposing electrode pad 30 toward a center of the LED chip 36. In this manner, vias 14 with larger diameters are arranged along center portions of the LED chip 36 that are between the opposing electrode pads 30.

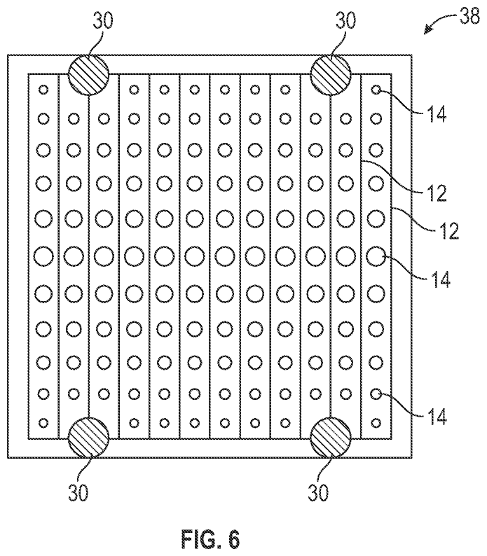

FIG. 6 is a top view of an LED chip 38 that is similar to the LED chip 36 of FIG. 5 and further includes multiple electrode pads 30 proximate each opposing edge of the LED chip 38. As illustrated, diameters of the vias 14 in each column increase with increasing distance from each opposing electrode pad 30 toward a center of the LED chip 38 in a manner similar to FIG. 5. By having multiple electrode pads 30 proximate each opposing edge, further improvements to current injection, current droop, and efficiency may be realized. As with previous embodiments, one or more, or even all of the electrode extensions 12 may form a continuous structure with all of the electrode pads 30.

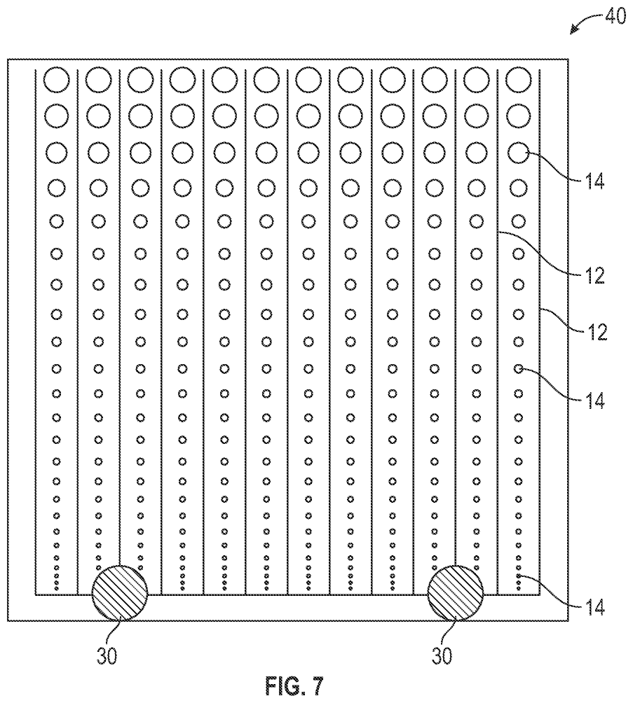

FIG. 7 is a top view of an LED chip 40 that is similar to the LED chip 32 of FIG. 3 for embodiments where a pitch of the vias 14 varies with distance from the electrode pad 30. As used herein, the pitch may refer to a distance between neighboring or next-adjacent vias 14 as measured between center points of the neighboring vias 14. As illustrated, the pitch between neighboring vias 14 is smaller proximate an edge of the LED chip 40 where the electrode pads 30 are located. In this manner, an increased quantity of vias 14 may be located near the electrode pads 30 where current injection may be highest. Within each column of vias 14, the pitch may increase with increasing distance from the electrode pads 30. In certain embodiments, diameters of vias 14 may also increase within each column of vias 14 with increasing distance from the electrode pads 30. For example, in FIG. 7, vias 14 with larger diameters are positioned proximate the opposing edge of the LED chip 40 from the electrode pads 30.

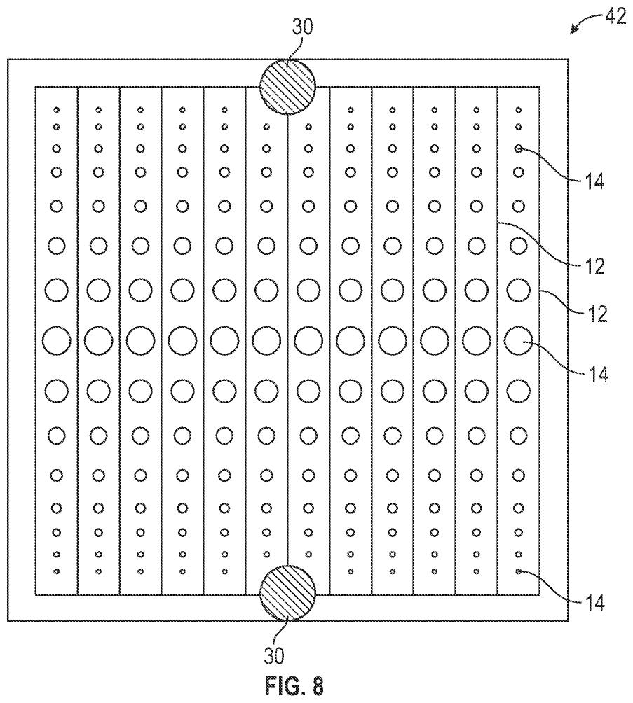

FIG. 8 is a top view of an LED chip 42 that is similar to the LED chip 40 of FIG. 7 except electrode pads 30 are positioned proximate opposing edges of the LED chip 42. In such an arrangement, the pitch between neighboring vias 14 in each column may increase toward a center of the LED chip 42 with increasing distance from each electrode pad 30. Accordingly, the highest pitch between neighboring vias 14 is formed at or near a center of each column of vias 14. As illustrated, diameters of the vias 14 may increase and then decrease along each column of vias 14. In this manner, diameters of the vias 14 in each column may increase with increasing distance from each opposing electrode pad 30 toward center portions of the LED chip 42 such that vias 14 with larger diameters are arranged along the center portions of the LED chip 42.

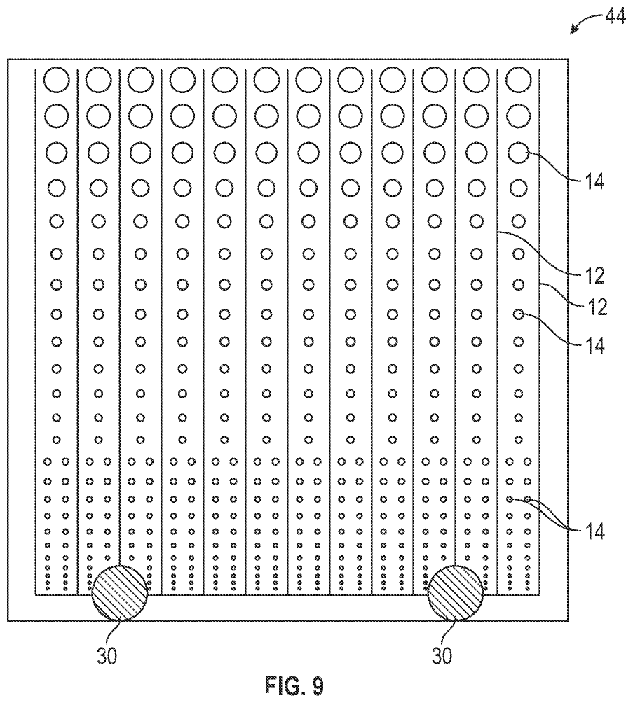

FIG. 9 is a top view of an LED chip 44 that is similar to the LED chip 40 of FIG. 7 for embodiments where vias 14 are formed in multiple columns between portions of adjacent electrode extensions 12. As described for FIG. 7, the pitch and diameter of vias 14 closest to the electrode pads 30 may be smaller than the pitch and diameter of vias 14 spaced farther away from the electrode pads 30. In this regard, the smaller pitch and diameter of vias 14 closer to the electrode pads 30 allows multiple columns of vias 14 in these locations. With increasing distance from the electrode pads 30, the pitch and diameter of the vias 14 may increase such that the vias 14 are arranged in a single column between neighboring electrode extensions 12.

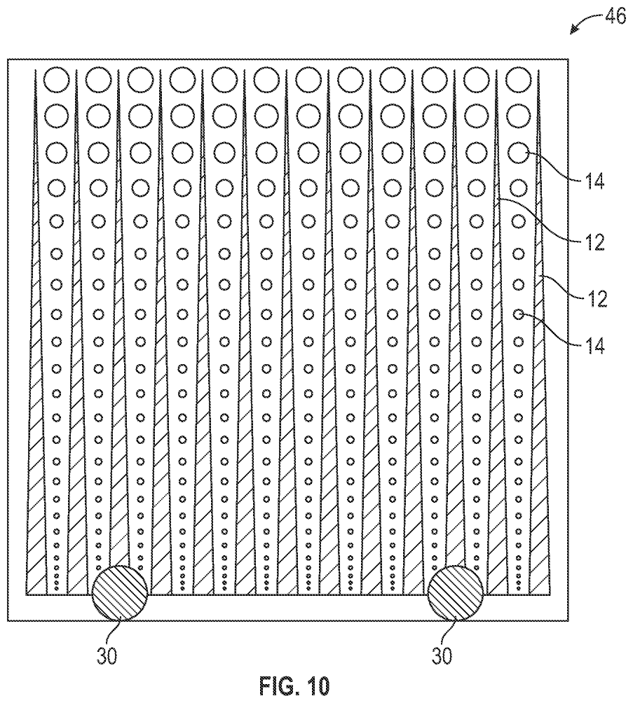

FIG. 10 is a top view of an LED chip 46 that is similar to the LED chip 40 of FIG. 7 for embodiments where a width of one or more of the electrode extensions 12 varies with distance from one or more of the electrode pads 30. For example, the width of one or more of the electrode extensions 12 is greater proximate the electrode pads 30 and narrower proximate the opposing edge of the LED chip 46 from the electrode pads 30. In this manner, the electrode extensions 12 are formed to cover an increased surface area of the LED chip 46 proximate the electrode pads 30 where current injection may be highest. As illustrated, the vias 14 in each column may have diameters and/or a pitch that increases with increasing distance from the electrode pads 30. Accordingly, largest diameter vias with the highest pitch may be positioned farthest from the electrode pads 30 and proximate narrowest widths of the electrode extensions 12. The opposing nature of decreasing widths of electrode extensions 12 and increasing pitch and/or diameters of the vias 14 may increase uniformity in lateral spacing between each via 14 and one or more closest electrode extensions 12. In this context, the lateral spacing may be measured in a direction perpendicular to each column of vias 14. As such, a position of each via 14 may be provided in areas with higher electric potential for increased emission efficiency while also providing improved current distribution across the LED chip 46.

FIG. 11 is a top view of an LED chip 48 that is similar to the LED chip 32 of FIG. 3 for embodiments where the electrode pad 30 is an electrode bar proximate an edge of the LED chip 32. As illustrated, each of the electrode extensions 12 connects with the electrode pad 30 proximate the edge of the LED chip 48. In certain embodiments, the electrode pad 30 is a single electrode pad that extends continuously between each of the electrode extensions 12. In still further embodiments, the electrode pad 30 has a length along the edge of the LED chip 48 that is greater than a distance of the array of vias 14 as measured between outermost columns of the vias. The single electrode pad 30 in the form of a bar as illustrated in FIG. 11 is advantageous for higher current applications. In this regard, multiple wire bonds may be electrically coupled to the single electrode pad 30. The diameters and/or spacing of vias 14 within each column may also be varied as previously described. The electrode pad 30 as illustrated in FIG. 11 may be implemented in any of the previous embodiments, including FIGS. 2 to 10.

FIG. 12 is a top view of an LED chip 50 that is similar to the LED chip 48 of FIG. 11 for embodiments where positions of vias 14 in each column are offset with positions of vias 14 in adjacent columns. The columns of vias 14 extend between opposing edges of the LED chip 50. As illustrated, positions of vias 14 in each column are offset such that linear rows of vias 14 in a direction between the other opposing edges of the LED chip 50, or perpendicular to the columns, are avoided. Such an arrangement may provide improved uniformity of vias 14 relative to electrode extensions 12 for increased carrier distribution uniformity. In certain embodiments, the offset nature of the vias 14 provides different total numbers of vias in adjacent columns. The diameters and/or spacing of vias 14 within each column may also be varied as previously described. The arrangement of vias 14 as illustrated in FIG. 12 may be implemented in any of the previous embodiments, including FIGS. 2 to 11.

As described above, principles of the present disclosure provide various layouts of vias, electrode extensions, and/or electrode pads that are tailored to localized electrostatic field differences in various LED chip structures. Such layouts may provide distributions of carriers (i.e., holes and electrons) with improved uniformity, thereby improving recombination efficiency for light generation while reducing localized heating from localized carrier concentrations.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure comprising a first layer of a first conductivity type, a second layer of a second conductivity type that is opposite the first conductivity type, and an active layer between the first layer and the second layer;
a first electrode pad on a first side of the active LED structure,
a first electrode extension and a second electrode extension on the first side of the active LED structure, the first electrode extension and the second electrode extension electrically connected to the first electrode pad; and
a plurality of vias on a second side of the active LED structure opposite the first side, the plurality of vias positioned between portions of the active LED structure that are vertically aligned with the first electrode extension and the second electrode extension, and diameters of individual vias of the plurality of vias vary with distance from the first electrode pad.

2. The LED chip of claim 1, wherein the plurality of vias is arranged in a column across the second side of the active LED structure.

3. The LED chip of claim 1, wherein the diameters of individual vias of the plurality of vias progressively decrease with increasing distance from the first electrode pad.

4. The LED chip of claim 1, wherein the diameters of individual vias of the plurality of vias progressively increase with increasing distance from the first electrode pad.

5. The LED chip of claim 1, further comprising a second electrode pad on the first side of the active LED structure, wherein the first electrode pad is arranged proximate a first edge of the active LED structure, the second electrode pad is arranged proximate a second edge of the active LED structure, and the second edge is opposite the first edge.

6. The LED chip of claim 5, wherein the diameters of individual vias of the plurality of vias progressively decrease with increasing distance from the first electrode pad and the second electrode pad toward a center of the active LED structure.

7. The LED chip of claim 5, wherein the diameters of individual vias of the plurality of vias progressively increase with increasing distance from the first electrode pad and the second electrode pad toward a center of the active LED structure.

8. The LED chip of claim 1, further comprising:
a second electrode pad, a third electrode pad, and a fourth electrode pad on the first side of the active LED structure;
wherein the first electrode pad and the second electrode pad are arranged proximate a first edge of the active LED structure, the third electrode pad and the fourth electrode pad are arranged proximate a second edge of the active LED structure, and the second edge is opposite the first edge.

9. The LED chip of claim 1, wherein the first electrode pad is an electrode bar arranged proximate a first edge of the active LED structure.

10. The LED chip of claim 1, wherein:
the active LED structure comprises a first edge and a second edge that are opposite one another, and a third edge and a fourth edge that are opposite one another;
the plurality of vias is arranged in a first column of vias and a second column of vias that both extend between the first edge and the second edge of the active LED structure; and
positions of vias in the first column of vias are offset relative to positions of vias in the second column in a direction from the third edge to the fourth edge.

11. The LED chip of claim 1, wherein:
the plurality of vias is arranged in a first column of vias and a second column of vias; and
a total number of vias in the first column of vias is different than a total number of vias in the second column of vias.

12. A light-emitting diode (LED) chip comprising:
an active LED structure comprising a first layer of a first conductivity type, a second layer of a second conductivity type that is opposite the first conductivity type, and an active layer between the first layer and the second layer;
a first electrode pad on a first side of the active LED structure,
a first electrode extension and a second electrode extension on the first side of the active LED structure, the first electrode extension and the second electrode extension electrically connected to the first electrode pad; and
a plurality of vias on a second side of the active LED structure opposite the first side, the plurality of vias positioned between portions of the active LED structure that are vertically aligned with the first electrode extension and the second electrode extension, and a pitch between neighboring vias of the plurality of vias varies with distance from the first electrode pad.

13. The LED chip of claim 12, wherein the plurality of vias is arranged in a column across the second side of the active LED structure, and the pitch increases with increasing distance from the first electrode pad.

14. The LED chip of claim 13, wherein diameters of individual vias of the plurality of vias increase along the column with increasing distance from the first electrode pad.

15. The LED chip of claim 12, further comprising:
a second electrode pad on the first side of the active LED structure, wherein the first electrode pad is arranged proximate a first edge of the active LED structure, the second electrode pad is arranged proximate a second edge of the active LED structure, and the second edge is opposite the first edge;
wherein the pitch between neighboring vias of the plurality of vias is highest proximate a center of the first side of the active LED structure.

16. The LED chip of claim 12, wherein:
the plurality of vias is arranged in a plurality of columns between the first electrode extension and the second electrode extension proximate the first electrode pad; and
the plurality of vias is arranged in a single column between the first electrode extension and the second electrode extension in a position that is spaced farther away from the first electrode pad than the plurality of columns.

17. The LED chip of claim 16, wherein diameters of individual vias of the plurality of vias increase with increasing distance from the first electrode pad.

18. The LED chip of claim 12, wherein the first electrode pad is an electrode bar arranged proximate a first edge of the active LED structure.

19. The LED chip of claim 12, wherein:
the active LED structure comprises a first edge and a second edge that are opposite one another, and a third edge and a fourth edge that are opposite one another;
the plurality of vias is arranged in a first column of vias and a second column of vias that both extend between the first edge and the second edge of the active LED structure; and
positions of vias in the first column of vias are offset relative to positions of vias in the second column in a direction from the third edge to the fourth edge.

20. The LED chip of claim 12, wherein:
the plurality of vias is arranged in a first column of vias and a second column of vias; and
a total number of vias in the first column of vias is different than a total number of vias in the second column of vias.

21. A light-emitting diode (LED) chip comprising:
an active LED structure comprising a first layer of a first conductivity type, a second layer of a second conductivity type that is opposite the first conductivity type, and an active layer between the first layer and the second layer;
an electrode pad on a first side of the active LED structure,
a plurality of vias on a second side of the active LED structure opposite the first side, wherein diameters of individual vias of the plurality of vias vary with distance from the electrode pad; and
a first electrode extension on the first side of the active LED structure, the first electrode extension electrically connected to the electrode pad, wherein a width of the first electrode extension varies with distance from the electrode pad.

22. The LED chip of claim 21, wherein the width of the first electrode extension progressively decreases with increasing distance from the electrode pad.

23. The LED chip of claim 22, further comprising a second electrode extension on the first side of the active LED structure, the second electrode extension electrically connected to the electrode pad, wherein a width of the second electrode extension progressively decreases with increasing distance from the electrode pad.

24. The LED chip of claim 23, wherein the plurality of vias is arranged in a column across the second side of the active LED structure between portions of the active LED structure that are vertically aligned with the first electrode extension and the second electrode extension.

25. The LED chip of claim 24, wherein a pitch between neighboring vias of the plurality of vias increases with increasing distance from the electrode pad.

26. The LED chip of claim 24, wherein diameters of individual vias of the plurality of vias increase along the column with increasing distance from the electrode pad.

27. The LED chip of claim 21, wherein the electrode pad is an electrode bar arranged proximate a first edge of the active LED structure.

28. The LED chip of claim 21, wherein:
the active LED structure comprises a first edge and a second edge that are opposite one another, and a third edge and a fourth edge that are opposite one another;
the plurality of vias is arranged in a first column of vias and a second column of vias that both extend between the first edge and the second edge of the active LED structure; and
positions of vias in the first column of vias are offset relative to positions of vias in the second column in a direction from the third edge to the fourth edge.

29. The LED chip of claim 21, wherein:
the plurality of vias is arranged in a first column of vias and a second column of vias; and
a total number of vias in the first column of vias is different than a total number of vias in the second column of vias.
